(19) United States
(12) Patent Application Publication
(10) Pub. No.: US 2012/0170376 A1
(43) Pub. Date: Jul. 5, 2012

(54) SEMICONDUCTOR MEMORY DEVICE AND OPERATING METHOD THEREOF

(75) Inventors: Hee Youl LEE, Icheon-si Gyeonggi-do (KR); Keun Woo LEE, Yongin-si Gyeonggi-do (KR)

(73) Assignee: Hynix Semiconductor Inc., Icheon-si (KR)

(21) Appl. No.: 13/339,092

(22) Filed: Dec. 28, 2011

(30) Foreign Application Priority Data
Dec. 30, 2010 (KR) 10-2010-0139186

(51) Int. Cl. G11C 16/06

(52) U.S. Cl. 365/185.22; 365/185.25

(57) ABSTRACT

A semiconductor memory device includes a plurality of memory cells, including an N well formed within a P type region and a P well formed within the N well, a peripheral circuit configured to perform a program, program verify, read, erase, or erase verify operation on memory cells selected from among the memory cells, a voltage supply circuit configured to generate a positive voltage and a negative voltage for the program, program verify, read, erase, or erase verify operation, and a control circuit configured to control the peripheral circuit and the voltage supply circuit so that the program, program verify, read, erase, or erase verify operation is performed and, when the program verify and read operations are performed, different voltage is supplied to the P well and the N well.

### CROSS-REFERENCE TO RELATED APPLICATION

The present application claims priority under 35 U.S.C. 119(a) to Korean patent application number 10-2010-0139186 filed on Dec. 30, 2010, the entire disclosure of which is incorporated by reference herein.

### BACKGROUND

1. Field of the Invention

Embodiments relate to a semiconductor memory device and an operating method thereof.

2. Description of the Related Art

As the size of semiconductor memory devices continue to be reduced, the size of a memory cell is reduced. An interval between the memory cells is also reduced. Accordingly, when data is programmed or read, an interference phenomenon may occur between adjacent memory cells.

FIG. 1 is a simplified sectional view of memory cells.

Referring to FIG. 1, memory cells C1, C2, and C3 include respective floating gates FG1, FG2, and FG3 and respective control gates CG. The memory cells C1, C2, and C3 are coupled to the same word line in a semiconductor memory device.

If the size of an active region is reduced in order to reduce the size of the memory cell, boron (B) is lost near an edge portion A of the channel region (the active region).

That is, if the widths of the active regions are reduced as the memory cells C1, C2, and C3 are reduced, a ratio of an edge region occupying an entire channel region is increased, and a ratio of a central portion occupied in the entire channel region is decreased. This makes it difficult to supplement the edge region with boron (B) within the central portion. Consequently, characteristics of the memory cell are deteriorated.

Furthermore, the memory cell C2 experiences increased interference due to the floating gates FG1 and FG3 of the memory cells C1 and C3 adjacent to the memory cell C2 in the direction of the word lines.

In this case, an interference phenomenon is generated in which a threshold voltage of the memory cell C2 is changed because of interference between the memory cell C2 and the floating gate FG1 and FG3. Also, the interference phenomenon may also be caused by a negative charge trap in the channel edge region that is increased as the erase/write (E/W) cycle of the memory cells is increased. Consequently, reliability of the memory cells may be deteriorated.

### BRIEF SUMMARY

Embodiments relate to a semiconductor memory device and an operating method thereof which are capable of controlling a program voltage or a program verify voltage supplied to the gate of a memory cell in a program or verify operation by differently controlling voltage supplied to the P well and the N well of the memory cell.

A semiconductor memory device according to an aspect of the present disclosure includes a plurality of memory cells, including an N well formed within a P type region and a P well formed within the N well, a peripheral circuit configured to perform a program, program verify, read, erase, or erase verify operation on memory cells selected from among the memory cells, a voltage supply circuit configured to generate a positive voltage and a negative voltage for the program, program verify, read, erase, or erase verify operation, and a control circuit configured to control the peripheral circuit and the voltage supply circuit so that the program, program verify, read, erase, or erase verify operation is performed and, when the program verify and read operations are performed, different voltage is supplied to the P well and the N well.

An operating method of a semiconductor memory device according to another aspect of the present disclosure includes supplying different voltage to a P well and an N well when a program verify operation and a read operation are performed on memory cells, including the N well formed within a P type region and the P well formed within the N well.

Still another embodiment discloses a memory cell comprising an N well and a P well configured to receive different voltage during a precharging operation.

### BRIEF DESCRIPTION OF THE DRAWINGS

FIG. 1 is a simplified sectional view of memory cells of a prior art device;

FIG. 2 shows a semiconductor memory device;

FIG. 3A shows a detailed construction of a memory cell array of FIG. 2;

FIG. 3B is a simplified cross-sectional view showing some memory cells of FIG. 3A;

FIG. 4 shows distributions of a threshold voltage of programmed memory cells;

FIG. 5 is a flowchart illustrating a program operation;

FIG. 6 shows a degree that a memory cell is programmed when a program voltage and voltage supplied to a P well are changed;

FIG. 7A shows a relationship between an E/W cycle and a cell current when a known program verify operation is performed;

FIG. 7B shows a relationship between an E/W cycle and a cell current when a program verify operation, such as that shown in FIG. 5, is performed; and

FIG. 8 shows a shift of a threshold voltage due to interference between floating gates in the direction of bit lines when a program verify operation, such as that shown in FIG. 5, is performed.

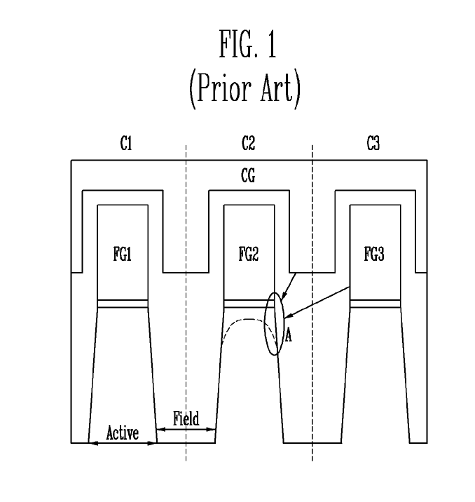

### DESCRIPTION OF EMBODIMENTS

Hereinafter, some embodiments of the present disclosure will be described in detail with reference to the accompanying drawings. The figures are provided to allow those having ordinary skill in the art to understand the scope of embodiments of the disclosure.

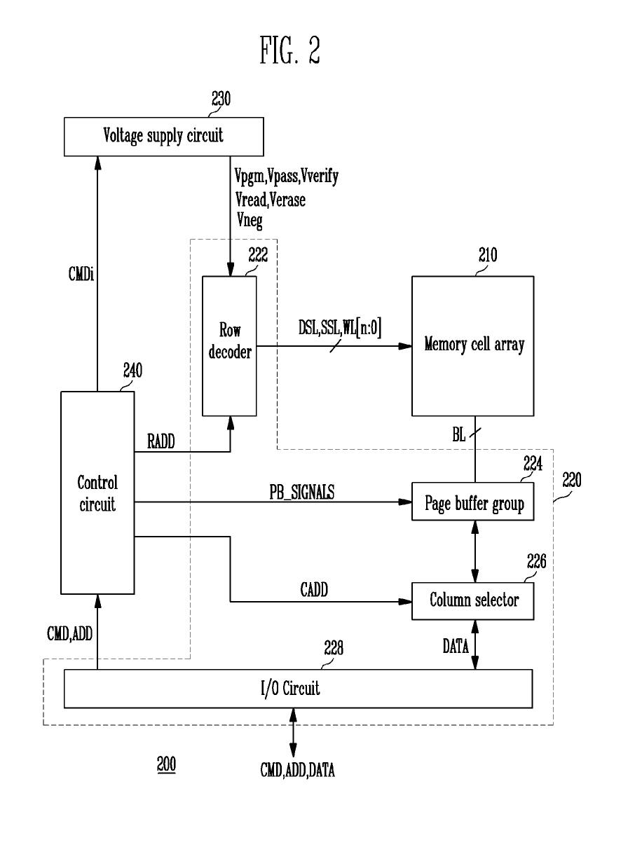

FIG. 2 shows a semiconductor memory device.

Referring to FIG. 2, the semiconductor memory device 200 includes a memory cell array 210, a peripheral circuit 220, a voltage supply circuit 230, and a control circuit 240.

The memory cell array 210 includes a plurality of memory cells for storing data. The peripheral circuit 220 includes circuits for performing an operation of programming data into the memory cells of the memory cell array 210, or reading or erasing data stored in the memory cells.

The peripheral circuit 220 may include, for example, a row decoder 222, a page buffer group 224, a column selector 226 and an I/O circuit 228.

The voltage supply circuit 230 generates operating voltages necessary for a program, read, or erase operation and supplies the voltage to the peripheral circuit 220, especially the row decoder 222. The operating voltages generated by the voltage supply circuit 230 may include a program voltage Vpgm, a pass voltage Vpass, a read voltage Vread, an erase voltage Verase, an verify voltage Vverify and a negative voltage Vneg.

To this end, the voltage supply circuit 230 includes pump circuits for generating a positive voltage and a negative voltage.

The control circuit 240 controls the peripheral circuit 220 and the voltage supply circuit 230 so that the program, read, and erase operations are performed. The control circuit 230 controls the row decoder 222 by outputting a row address RADD, the page buffer group by outputting page buffer control signals PB_SIGNALS, the column selector 226 by outputting a column address CADD. The control circuit 230 controls levels and output timings of the operating voltages by controlling the voltage supply circuit 230 through an internal command CMDi.

The memory cell array 210 is described in more detail below.

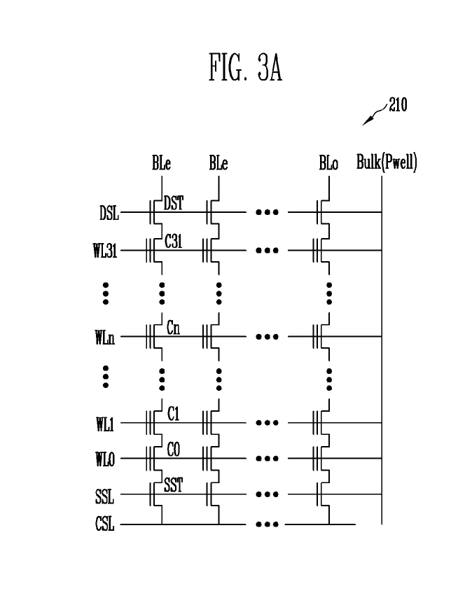

FIG. 3A shows a detailed construction of the memory cell array 210 of FIG. 2.

The memory cell array 210 includes memory blocks each including a plurality of memory cells.

The memory blocks share bit lines. A program, read, or erase operation is performed on a memory block by having the peripheral circuit 220 supply operating voltages to a memory block. In particular, the erase operation is performed per memory block.

The circuits of a memory block of the memory cell array 210 of FIG. 2 are shown in FIG. 3A.

The memory block of the memory cell array 210 includes a plurality of cell strings.

Each of the cell strings includes a drain select transistor DST, a source select transistor SST, and 0^{th} to 31^{st} memory cells C0 to C31.

The 0^{th} to 31^{st} memory cells C0 to C31 are in series with the drain select transistor DST and the source select transistor SST.

A gate of the drain select transistor DST is coupled to a drain select line DSL, and a gate of the source select transistor SST is coupled to a source select line SSL.

Gates of the 0^{th} to 31^{st} memory cells C0 to C31 are coupled to 0^{th} to 31^{st} word lines WL0 to WL31, respectively.

Drains of the drain select transistors DST are coupled to respective bit lines BL, and sources of the source select transistors SST are coupled to a common source line CSL. The bit lines BL are divided into even bit lines BLe and odd bit lines BLo.

FIG. 3B is a simplified cross-sectional view showing some memory cells of FIG. 3A. The cross section of memory cells coupled to the same word line is shown in FIG. 3B.

Referring to FIG. 3B, the memory cells have a structure in which the floating gates FG and the control gates CG are formed over a triple well structure in which an N well and a P well are coated on a substrate P-sub (i.e., a P type region of the substrate).

Threshold voltages of the memory cells of the semiconductor memory device 200 change depending on data stored in the memory cells.

If the memory cells are multi-level cells (MLC), the threshold voltages of the memory cells have first to fourth distributions.

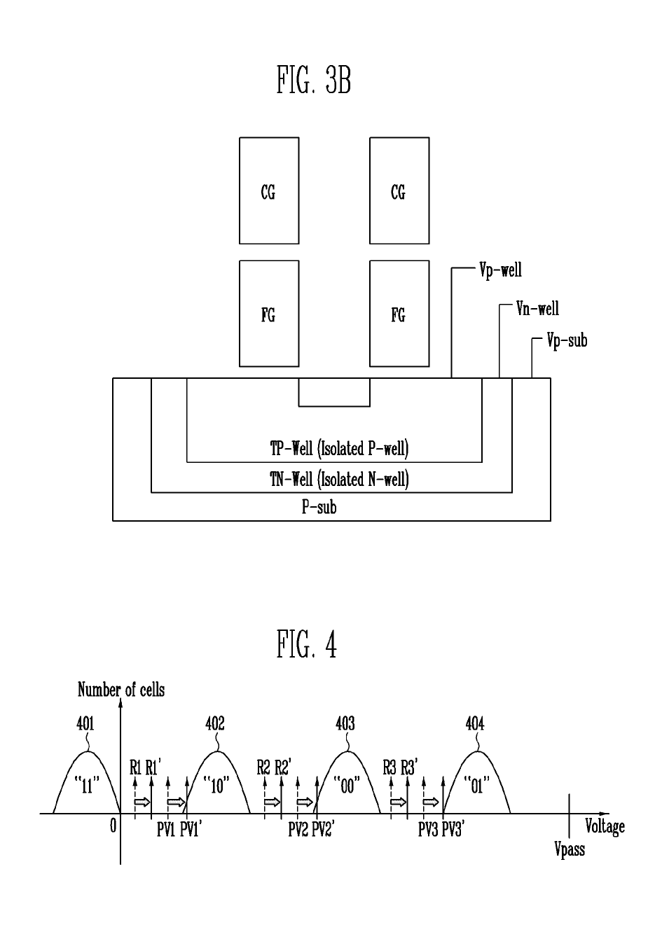

FIG. 4 shows distributions of threshold voltages of programmed memory cells.

Referring to FIG. 4, when memory cells having multiple levels are programmed, the threshold voltages of the memory cells belong to any one of the first to fourth distributions 401 to 404.

In an embodiment of this disclosure, in order to program the memory cells, voltage supplied to the P well and the N well of the memory block is controlled. A P well voltage Vp_well supplied to the P well and an N well voltage Vn_well supplied to the N well are controlled as follows.

When a program verify or read operation is performed, the speed that the threshold voltages of the memory cells rises becomes fast in relation to the voltage supplied to the P well or the N well.

In other words, when the program verify operation is performed, there is an effect that program verify voltages PV1 to PV3 rise to program verify voltages PV1′ to PV3′, respectively.

Furthermore, when the read operation is performed, there is an effect that read voltages R1 to R3 rise to read voltages R1′ to R3′, respectively. Accordingly, the program verify operation or the read operation can be performed by employing an effect that a threshold voltage is greatly changed by performing a small number of program operations. Consequently, the program voltage can be lowered as much as the effect.

Table 1 shows voltages supplied according to a first embodiment of this disclosure.

TABLE 1

| | | Program | | |
|---|---|---|---|---|
| | Program | verify | Read | Erase verify |
| Vp_well | Negative | Negative | Negative | Negative |
| | voltage | voltage | voltage | voltage |
| Vn_well | Positive | Positive | Positive | Positive |
| | voltage | voltage | voltage | voltage |

As shown Table 1, when the program, program verify, the read operation, and the erase verify operation are performed, the voltage Vp_well supplied to the P well is the negative voltage, and the voltage Vn_well supplied to the N well is the positive voltage.

For example, the program operation is described in detail below.

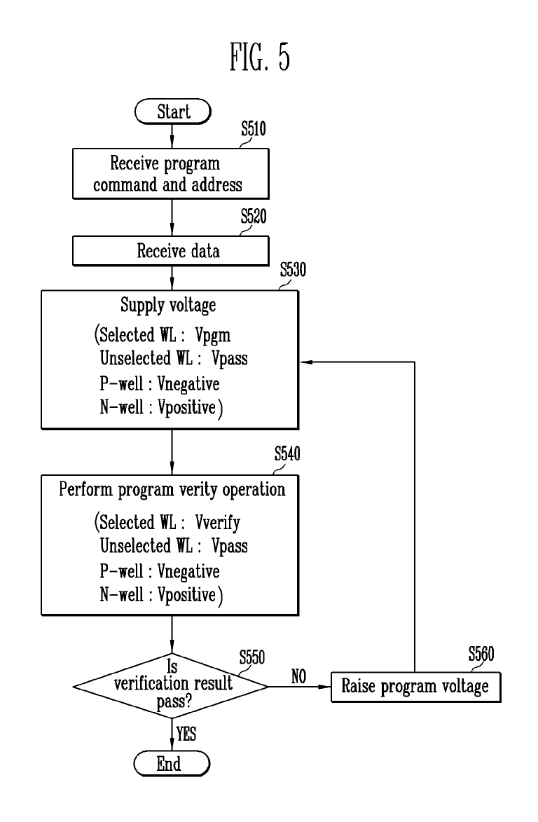

FIG. 5 is a flowchart illustrating a program operation.

Referring to FIG. 5, for the program operation, a program command and an address are inputted to the semiconductor memory device, and data to be programmed is then inputted thereto at steps S510 and S520.

The program command and the address are transferred to the control circuit 240 via the peripheral circuit 220. The data to be programmed is stored in a page buffer (not shown) included in the page buffer group 224 of the peripheral circuit 220.

The control circuit 240 inputs a control signal to the voltage supply circuit 230 so that the operating voltages are generated.

The operating voltages, as described above, include the program voltage Vpgm, the pass voltage Vpass, etc.

The control circuit 240 selects a memory block to be enabled based on the address received at step S510 and selects a word line and bit lines to be programmed.

The program voltage Vpgm is supplied to the selected word line, and the pass voltage Vpass is supplied to the remaining word lines. Furthermore, a negative voltage is supplied to the P well, and a positive voltage is supplied to the N well.

The voltages may start being supplied to the P well and the N well while the bit lines are precharged for the program operation.

The data is programmed into selected memory cells, coupled to the selected word line and the selected bit lines, in response to the operating voltage at step S530.

Next, the program verify operation for checking whether the selected memory cells have been programmed is performed at step S540.

When the program verify operation is performed, the program verify voltages are supplied to the selected word line and the pass voltage is supplied to the unselected word lines. Furthermore, as shown in Table 1, the negative voltage is supplied to the P well, and the positive voltage is supplied to the N well. The voltages start being supplied to the P well and the N well while the bit lines are precharged for the program verify operation.

Here, the negative voltage is lower than 0 V, preferably, about −3 V. Furthermore, the positive voltage supplied to the N well is lower than 1 V. Positive voltage is supplied to the N well to prevent leakage current from occurring between the P and N wells due to noise resulting from coupling when the negative voltage is supplied to the P well.

When the negative voltage and the positive voltage are supplied to the P well and the N well as described above, an electric potential in the P well is increased and a potential barrier between the P well and the drain and source of the memory cell may be formed of an n type, thereby making electrons difficult to be injected. In other words, a channel is formed when a high voltage is supplied to the gate of a memory cell. Accordingly, while the program verify operation is performed, the selected memory cells are not programmed.

Furthermore, there is no load of the leakage current because a length of the channel is reduced.

After the program verify operation is performed, it is checked whether a result of the program verify operation is a pass (that is, whether the program operation on all the memory cells is a pass) at step S550. If, as a result of the check, the result of the program verify operation is a pass, the program operation is finished. If, as a result of the check, the result of the program verify operation is not a pass, the program voltage is raised according to an increment step pulse program (ISPP) method at step S560, and the process returns to step S530.

The method of supplying the negative voltage and the positive voltage to the P well and the N well when the program verify operation is performed may also be applied to a data read operation and an erase verify operation without change.

In this case, voltage supplied to the P well in the erase verify operation may be equal to or lower than voltage supplied to the P well in the program verify operation or the data read operation.

That is, when the read operation or the erase verify operation is performed, negative voltage is supplied to the P well and positive voltage is supplied to the N well.

The embodiment of Table 1 and FIG. 5 shows that the negative voltage is supplied to the P well and the positive voltage is supplied to the N well when the program, program verify, read, and erase verify operations are performed.

In another embodiment, in the program verify, read, and erase verify operations, a negative voltage is supplied to the P well and a positive voltage is supplied to the N well. In the program verify operation, 0 V may be supplied to the P well and the N well. In this case, a similar effect can be obtained.

In yet another embodiment, only in the program verify operation and the read operation, the negative voltage is supplied to the P well and the positive voltage is supplied to the N well. The program verify operation and the erase verify operation are performed using a known method. In this case, a similar effect can be obtained.

According to the embodiments, when the program verify operation or the read operation is performed, negative voltage is supplied to the P well, and the positive voltage is supplied to the N well. When the remaining operations (for example, the program operation or the erase verify operation) are performed, negative voltage may be selectively supplied to the P well and positive voltage may be selectively supplied to the N well.

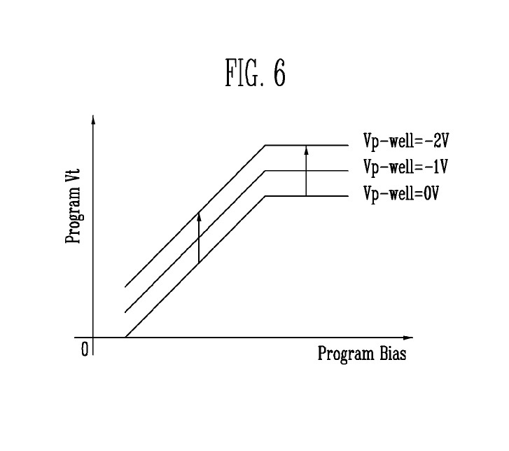

FIG. 6 shows a degree that a memory cell is programmed when a program voltage and voltage supplied to a P well are changed.

FIG. 6 shows that a degree that the threshold voltage of a memory cell rises according to a program voltage becomes high according to a lower voltage supplied to the P well.

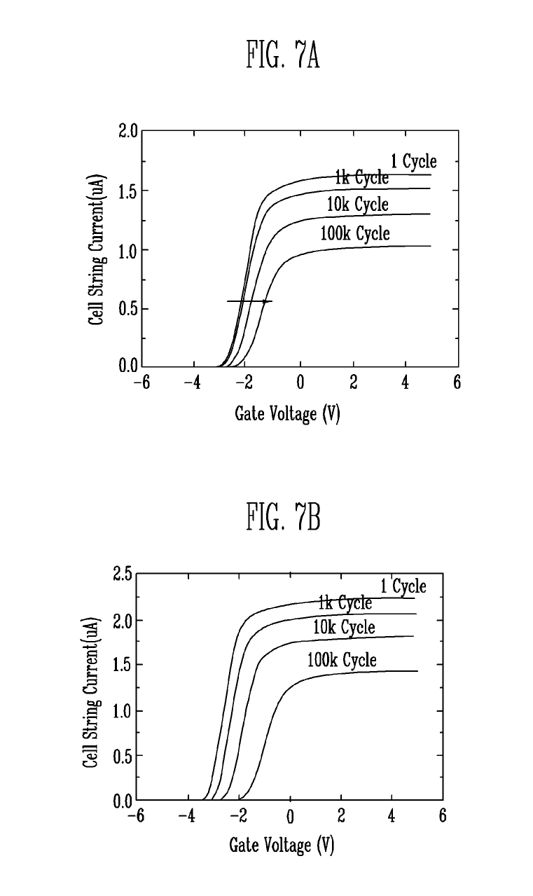

FIG. 7A shows a relationship between an E/W cycle and a cell current when a known program verify operation is performed, and FIG. 7B shows a relationship between an E/W cycle and a cell current when a program verify operation, such as that shown in FIG. 5, is performed.

From FIGS. 7A and 7B, it can be seen that cell characteristics become better when negative voltage is supplied to the P well and positive voltage is supplied to the N well when the program verify operation is supplied.

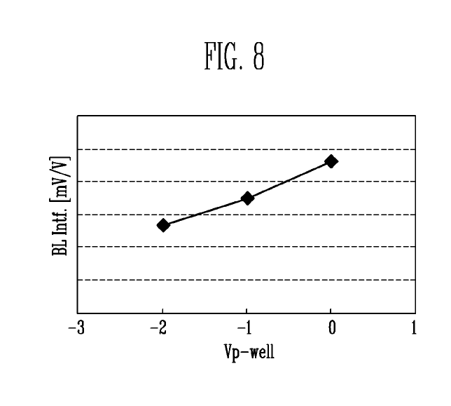

FIG. 8 shows a shift of a threshold voltage due to interference between floating gates in the direction of the bit lines when a program verify operation, such as that shown in FIG. 5, is performed.

From FIG. 8, it can be seen that influence due to interference between the floating gate in the direction of the bit lines is reduced according to a reduction in the voltage supplied to the P well.

Table 2 shows voltages supplied according to a second embodiment of this disclosure.

TABLE 2

| | | Program | | |
|---|---|---|---|---|
| | Program | verify | Read | Erase verify |
| Vp_well | Negative | Negative | Negative | Negative |
| | voltage | voltage | voltage | voltage |
| Vn_well | 0 V | 0 V | 0 V | 0 V |

Referring to Table 2, when program, program verify, read, and erase verify operations are performed, negative voltage is supplied to the P well and 0 V is supplied to the N well.

That is, when step S530 of FIG. 5 is performed, the program voltage Vpgm is supplied to the selected word line, the pass voltage is supplied to the unselected word lines, the negative voltage is supplied to the P well, and 0 V is supplied to the N well.

The voltages start being supplied to the P well and the N well when voltage supplied to the bit lines is set for the program operation.

When the program verify operation of step S540 is performed, negative voltage is supplied to the P well and 0 V is supplied to the N well.

Furthermore, in the read operation and the erase verify operation, negative voltage is supplied to the P well and 0 V is supplied to the N well.

When the program, program verify, read, and erase verify operations are performed according to the first and the second embodiments of this disclosure, negative voltage is supplied to the P well, and the positive voltage or 0 V (i.e., non-negative voltage) is supplied to the N well so that the P well and the N well are separated from each other. In this case, a problem that a program becomes fast owing to the negative voltage supplied to the P well and an interference problem in which the threshold voltage of a problem-inhibited cell is changed by adjacent cells can be reduced.

In the second embodiment of Table 2, in the program, program verify, read, and erase verify operations, negative voltage is supplied to the P well and 0 V is supplied to the N well.

In another embodiment, in the program verify, read, and erase verify operations, negative voltage is supplied to the P well and the 0 V is supplied to the N well. In the program verify operation, 0 V is supplied to the P well and the N well. In this case, a similar effect can be obtained.

In yet another embodiment, only in the program verify operation and the read operation, the negative voltage is supplied to the P well and the 0 V is supplied to the N well. The program verify operation and the erase verify operation are performed using a known method. In this case, a similar effect can be obtained.

According to the embodiments, when the program verify operation or the read operation is performed, negative voltage is supplied to the P well, and 0 V is supplied to the N well. When the remaining operations (for example, the program operation or the erase verify operation) are performed, negative voltage may be selectively supplied to the P well and 0 V may be selectively supplied to the N well.

In the semiconductor memory device and the operating method thereof according to the embodiments of this disclosure, when the program operation or verify operation is performed, a negative voltage is supplied to the P well and a different voltage is supplied to the N well. Accordingly, interference between memory cells can be prevented, deterioration characteristics of the memory cells can be prevented, and program speed can be increased.

What is claimed is:

1. A semiconductor memory device, comprising:
a plurality of memory cells, including an N well formed within a P type region and a P well formed within the N well;
a peripheral circuit configured to perform a program, program verify, read, erase, or erase verify operation on memory cells selected from among the memory cells;
a voltage supply circuit configured to generate a positive voltage and a negative voltage for the program, program verify, read, erase, or erase verify operation; and
a control circuit configured to control the peripheral circuit and the voltage supply circuit so that the program, program verify, read, erase, or erase verify operation is performed and, when the program verify and read operations are performed, different voltage is supplied to the P well and the N well.

2. The semiconductor memory device of claim 1, wherein the control circuit controls the peripheral circuit and the voltage supply circuit so that the negative voltage is supplied to the P well and the positive voltage or 0 V is supplied to the N well.

3. The semiconductor memory device of claim 2, wherein the negative voltage and the positive voltage or 0 V start being supplied to the P well the N well, respectively, when bit lines coupled to the memory cells are precharged.

4. The semiconductor memory device of claim 2, wherein the control circuit controls the peripheral circuit and the voltage supply circuit so that the negative voltage is supplied to the P well and the positive voltage or 0 V is supplied to the N well when at least one of the program operation and erase verify operation is performed.

5. An operating method of a semiconductor memory device, comprising:
supplying different voltage to a P well and an N well when a program verify operation and a read operation are performed on memory cells, including the N well formed within a P type region and the P well formed within the N well.

6. The operating method of claim 5, wherein the negative voltage and the positive voltage or 0 V are supplied to the P well and the N well, respectively.

7. The operating method of claim 6, wherein the negative voltage and the positive voltage or 0 V are supplied to the P well and the N well, respectively, when voltage supplied to bit lines coupled to the memory cells is precharged in order to perform the program, program verify, read, or erase verify operation.

8. The operating method of claim 6, further comprising:
performing a program operation by supplying a program voltage to a word line coupled to memory cells selected from among the memory cells, a pass voltage to unselected word lines coupled to unselected memory cells, the negative voltage to the P well, and the positive voltage or 0 V to the N well, before performing the program verify operation; and
performing the program verify operation by supplying a program verify voltage to the selected word line, the pass voltage to the unselected word lines, the negative voltage to the P well, and the positive voltage or 0 V to the N well.

9. The operating method of claim 8, wherein the negative voltage supplied to the P well is lower than 0 V, but higher than −3 V.

10. The operating method of claim 6, further comprising:
performing a program operation by supplying a program voltage to a word line coupled to memory cells selected from among the memory cells and supplying a pass voltage to unselected word lines coupled to unselected memory cells, before performing the program verify operation; and
performing the program verify operation by supplying a program verify voltage to the selected word line, the pass voltage to the unselected word lines, the negative voltage to the P well, and the positive voltage or 0 V to the N well.

11. The operating method of claim 6, wherein the read operation is performed by supplying a read voltage to a selected word line coupled to memory cells selected from among the memory cells, a pass voltage to unselected word lines coupled to unselected memory cells, the negative voltage to the P well, and the positive voltage or 0 V to the N well.

12. The operating method of claim 6, further comprising:
performing an erase operation by supplying an erase voltage to the P well of a selected memory block, before performing an erase verify operation, and
performing the erase verify operation by supplying a negative voltage to the P well and the positive voltage or 0 V to the N well.

13. A memory cell comprising:
an N well and a P well configured to receive different voltages during a precharging operation.

14. The memory cell of claim 13, wherein the N well is configured to receive a non-negative voltage during the precharging operation and the P well is configured to receive a negative voltage during the precharging operation.

15. The memory cell of claim 14, wherein the P well is formed within the N well.

16. The memory cell of claim 15, wherein the N well is formed within a P type region of a substrate.

17. The memory cell of claim 14, wherein the memory cell is coupled to a bit line and begins to receive the negative and non-negative voltage while the bit line is being precharged.

18. The memory cell of claim 14, wherein one of a program, program verify, and read operation is performed by applying a pass voltage to a word line coupled to the memory cell if the word line is unselected.

19. The memory cell of claim 14, wherein the negative voltage supplied to the P well is lower than 0 V but higher than −3V.

20. The memory cell of claim 14, wherein the non-negative voltage is 0 V.

21. The memory cell of claim 14, wherein the negative and non-negative voltages are supplied when one of an erase or erase verify operation is performed on the memory cell.

22. The memory cell of claim 14, wherein the negative or non-negative voltages are supplied when one of a program or a program verify operation is performed on the memory cell.

23. The memory cell of claim 14, wherein the memory cell is disposed within a memory cell array.
